(19) United States
(12) Patent Application Publication
(10) Pub. No.: US 2014/0263173 A1
(43) Pub. Date: Sep. 18, 2014

(54) METHODS FOR IMPROVING ETCHING RESISTANCE FOR AN AMORPHOUS CARBON FILM

(71) Applicant: Applied Materials, Inc., Santa Clara, CA (US)

(72) Inventors: Craig ROSSLEE, San Jose, CA (US); Srinivas D. NEMANI, San Jose, CA (US); Dmitry LUBOMIRSKY, Cupertino, CA (US); Ellie Y. YIEH, San Jose, CA (US)

(73) Assignee: Applied Materials, Inc., Santa Clara, CA (US)

(21) Appl. No.: 14/201,737

(22) Filed: Mar. 7, 2014

Related U.S. Application Data
(60) Provisional application No. 61/787,071, filed on Mar. 15, 2013.

(51) Int. Cl. B05D 3/06; H01J 37/30

(52) U.S. Cl. CPC B05D 3/06; H01J 37/3007
USPC 216/48; 427/551; 250/492.3

(57) ABSTRACT

Methods for using an electron beam treatment performed on an amorphous carbon layer to form a treated amorphous carbon layer with high etching resistance are provided. In one embodiment, a method of treating an amorphous carbon film includes providing a substrate having a material layer disposed, forming an amorphous carbon layer on the material layer, and performing an electron beam treatment process on the amorphous carbon layer.

### CROSS-REFERENCE TO RELATED APPLICATION

This application claims benefit of U.S. Provisional Application Ser. No. 61/787,071 filed Mar. 15, 2013 (Attorney Docket No. APPM/17402L), which is incorporated by reference in its entirety.

### BACKGROUND

1. Field of the Invention

The present invention relates to the fabrication of integrated circuits and to a process for forming materials with high etching resistance on a substrate. More specifically, the invention relates to a process for improving etching resistance for a carbon containing material for semiconductor applications.

2. Description of the Background Art

Integrated circuits have evolved into complex devices that can include millions of transistors, capacitors and resistors on a single chip. The evolution of chip designs continually requires faster circuitry and greater circuit density. The demands for faster circuits with greater circuit densities impose corresponding demands on the materials used to fabricate such integrated circuits. In particular, as the dimensions of integrated circuit components are reduced to the sub-micron scale, it is now necessary to use low resistivity conductive materials (e.g., copper) as well as low dielectric constant insulating materials (dielectric constant less than about 4) to obtain suitable electrical performance from such components.

The demands for greater integrated circuit densities also impose demands on the process sequences used in the manufacture of integrated circuit components. For example, in process sequences that use conventional photo lithographic techniques, a layer of energy sensitive resist is formed over a stack of material layers disposed on a substrate. The energy sensitive resist layer is exposed to an image of a pattern to form a photoresist mask. Thereafter, the mask pattern is transferred to one or more of the material layers of the stack using an etch process. The chemical etchant used in the etch process is selected to have a greater etch selectivity for the material layers of the stack than for the mask of energy sensitive resist. That is, the chemical etchant etches the one or more layers of the material stack at a rate much faster than the energy sensitive resist. The etch selectivity to the one or more material layers of the stack over the resist prevents the energy sensitive resist from being consumed prior to completion of the pattern transfer. Thus, a highly selective etchant enhances accurate pattern transfer.

As the geometry limits of the structures used to form semiconductor devices are pushed against technology limits, the need for accurate pattern transfer for the manufacture of structures having small critical dimensions and high aspect ratios has become increasingly difficult. For example, the thickness of the energy sensitive resist has been reduced in order to control pattern resolution. Such thin resist layers (e.g., less than about 2000 Å) can be insufficient to mask underlying material layers during the pattern transfer step due to attack by the chemical etchant. An intermediate layer (e.g., silicon oxynitride, silicon carbine or carbon film), called a hardmask layer, is often used between the energy sensitive resist layer and the underlying material layers to facilitate pattern transfer because of its greater resistance to chemical etchants. When etching materials to form structures having aspect ratios greater than about 5:1 and/or critical dimensional less than about 50 nm, the hardmask layer utilized to transfer patterns to the materials is exposed to aggressive etchants for a significant period of time. After a long period of exposure to the aggressive etchants, the hardmask layer without sufficient etching resistance may be damaged, resulting in inaccurate pattern transfer and loss of dimensional control. Additionally, stress in the deposited film and/or hardmask layer may also result in stress induced line edge bending and/or line breakage.

Therefore, there is a need in the art for an improved hardmask layer with high etching resistance during an etching process.

### SUMMARY

Methods for using an electron beam treatment performed on an amorphous carbon layer to form a treated amorphous carbon layer with high etching resistance are provided. In one embodiment, a method of treating an amorphous carbon film includes providing a substrate having a material layer disposed, forming an amorphous carbon layer on the material layer, and performing an electron beam treatment process on the amorphous carbon layer.

In another embodiment, a method to perform an electron beam treatment process on an amorphous carbon layer includes providing a substrate having an amorphous carbon layer disposed thereon, performing an electron beam treatment process on the amorphous carbon layer, wherein the electron beam treatment process further includes providing a first high voltage level and a first bias voltage level to generate an electron beam to the amorphous carbon layer for a first period of time, providing a second high voltage level and a second bias voltage level to generate the electron beam to the amorphous carbon layer for a second period of time, wherein the second high voltage level is less than the first high voltage level and the second bias voltage level is greater than the first bias voltage, and providing a third high voltage level and a third bias voltage level to generate the electron beam to the amorphous carbon layer for a third period of time, wherein the third high voltage level is less than the second high voltage level and the third bias voltage level is greater than the second bias voltage.

In yet another embodiment, a method of treating an amorphous carbon film using as an hardmask layer during an etching process includes providing a substrate having a material layer disposed, forming an amorphous carbon layer on the material layer, and performing an electron beam treatment process on the amorphous carbon layer, and etching the material layer using the treated amorphous carbon layer as a hardmask layer, wherein the electron beam treatment process further includes providing a first high voltage level and a first bias voltage level to generate an electron beam to the amorphous carbon layer for a first period of time, providing a second high voltage level and a second bias voltage level to generate the electron beam to the amorphous carbon layer for a second period of time, wherein the second high voltage level is less than the first high voltage level and the second bias voltage level is greater than the first bias voltage, and providing a third high voltage level and a third bias voltage level to generate the electron beam to the amorphous carbon layer for a third period of time, wherein the third high voltage level is less than the second high voltage level and the third bias voltage level is greater than the second bias voltage.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a cross-sectional diagram of an exemplary electron beam apparatus that can be used for the practice of this invention;

FIG. 2 depicts a enlarged view of a portion of the electron beam apparatus depicted in FIG. 1;

FIG. 3 depicts a schematic illustration of a deposition apparatus with an integrated electron beam source that can be used to practice embodiments of the invention;

FIG. 4 depicts a flow process diagram of a film formation process according to one embodiment of the present invention; and

FIGS. 5A-5D depict a sequence of schematic cross-sectional views of a substrate structure incorporating an amorphous carbon layer with high etching resistance formed according to the method of FIG. 4.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention provides a method of performing an electron beam treatment process on an amorphous carbon layer to form a treated amorphous carbon layer with high etching resistance. In one embodiment, the amorphous carbon film is suitable for use as a hardmask layer. During the electron beam treatment process, the energy provided by the electron beam densifies the film structure of the amorphous carbon film, thereby producing the amorphous carbon layer with high density along with high etching resistance. The electron beam treated amorphous carbon film have desired mechanical properties, such as high density, hardness and suitable range of stress, which provides high film selectivity and etching resistance to other material layers for the subsequent etching process, thereby enabling good pattern transfer of small features to the underlying film stack with good profile control. Additionally, the electron beam treated amorphous carbon film also provides desired optical film properties, such as desired range of index of refraction (n) and the absorption coefficient (k), which are advantageous for photolithographic patterning processes.

FIG. 1 illustrates an electron beam apparatus 100 that may be utilized to treat an amorphous carbon according to one embodiment of the invention. An example of such an electron beam apparatus is EBK™ twin chamber on Producer® system, available from Applied Materials, Inc. of Santa Clara, Calif. The chamber 100 includes a substrate support 130 disposed in a vacuum chamber 120 having an electron beam generating system 150 disposed above the substrate support 130. The electron beam generating system 150 includes a large-area cathode 122, a field-free region 138, and a grid anode 126 positioned between the substrate support 130 and the large-area cathode 122. A high voltage insulator 124 is disposed in the electron beam generating system 150 isolating the grid anode 126 from the large-area cathode 122. A cathode cover insulator 128 is located outside the vacuum chamber 120. A variable leak valve 132 is utilized to control the pressure inside the vacuum chamber 120. A variable high voltage power supply 129 is connected to the large-area cathode 122, and a variable low voltage power supply 131 is connected to the grid anode 126.

In operation, the substrate (not shown) to be exposed with the electron beam generated from the electron beam generating system 150 is placed on the substrate support 130. The vacuum chamber 120 is pumped from atmospheric pressure to a pressure in the range of about 1 mTorr to about 200 mTorr. The exact pressure is controlled by the variable rate leak valve 132, which is capable of controlling pressure to about 0.1 mTorr. The electron beam is generally generated at a sufficiently high voltage, which is applied to the large-area cathode 122 by the high voltage power supply 129. The voltage may range from about −500 volts to about 30,000 volts or higher. The high voltage power supply 129 may be a Bertan Model #105-30R manufactured by Bertan of Hickville, N.Y., or a Spellman Model #SL30N-1200X 258 manufactured by Spellman High Voltage Electronics Corp., of Hauppauge, N.Y. The variable voltage power supply 131 applies a voltage to the grid anode 126 that is positive relative to the voltage applied to the large-area cathode 122. This voltage is used to control electron emission from the large-area cathode 122. The variable voltage power supply 131 may be an Acopian Model #150PT12 power supply available from Acopian of Easton, Pa.

To initiate electron emission, the gas in the space between the large-area cathode 122 and the substrate support 130 is ionized, which may occur as a result of naturally occurring gamma rays. Electron emission may also be artificially initiated inside the vacuum chamber 120 by a high voltage spark gap. Once this initial ionization takes place, positive ions 242 (shown in FIG. 2) are attracted to the grid anode 126 by a slightly negative voltage, i.e., on the order of about 0 to about −200 volts, applied to the grid anode 126. These positive ions 242 pass into the accelerating field region 136, disposed between the large-area cathode 122 and the grid anode 126, and are accelerated towards the large-area cathode 122 as a result of the high voltage applied to the large-area cathode 122. Upon striking the large-area cathode 122, these high-energy ions produce secondary electrons 244, which are accelerated back toward the grid anode 126. Some of these electrons, which travel generally perpendicular to the cathode surface, strike the grid anode 126, but many pass through the anode 126 and travel to the substrate support 130. The grid anode 126 is positioned at a distance less than the mean free path of the electrons emitted by the large-area cathode 122, e.g., the grid anode 126 is preferably positioned less than about 4 mm from the large-area cathode 122. Due to the short distance between the grid anode 126 and the large-area cathode 122, no, or minimal if any, ionization takes place in the accelerating field region 136 between the grid anode 126 and the large-area cathode 122.

In a gas discharge device, the electrons would create further positive ions in the accelerating field region, which would be attracted to the large-area cathode 122, creating even more electron emission. The discharge could easily avalanche into an unstable high voltage breakdown. However, in accordance with an embodiment of the invention, the ions 242 created outside the grid anode 2126 may be controlled (repelled or attracted) by the voltage applied to the grid anode 126. In other words, the electron emission may be continuously controlled by varying the voltage on the grid anode 126. Alternatively, the electron emission may be controlled by the variable leak valve 132, which is configured to raise or lower the number of molecules in the ionization region between the substrate support 130 and the large-area cathode 122. The electron emission may be entirely turned off by applying a positive voltage to the grid anode 126, i.e., when the grid anode voltage exceeds the energy of any of the positive ion species created in the space between the grid anode 126 and target plane 130.

FIG. 3 is a cross sectional schematic diagram of a chemical vapor deposition chamber 300 having an electron beam generating system, such as the electron beam generating system 150 depicted in FIGS. 1-2, incorporated therein, which may be used for practicing embodiments of the invention. An example of such a chamber is a dual or twin chamber of a PRODUCER® system, available from Applied Materials, Inc. of Santa Clara, Calif. The twin chamber has two isolated processing regions (for processing two substrates, one substrate per processing region) such that the flow rates experienced in each region are approximately one half of the flow rates into the whole chamber. The flow rates described in the examples below and throughout the specification are the flow rates for processing, a 200 mm substrate, a 300 mm substrate or a 450 mm substrate. A chamber having two isolated processing regions is further described in U.S. Pat. No. 5,855,681, which is incorporated by reference herein. Another example of a chamber that may be used is a DxZ® chamber on a CENTURA® system which are available from Applied Materials, Inc.

The CVD chamber 300 has a chamber body 302 that defines separate processing regions 318, 320. Each processing region 318, 320 has a pedestal 328 for supporting a substrate (not shown) within the CVD chamber 300. Each pedestal 328 typically includes a heating element (not shown). Each pedestal 328 is movably disposed in one of the processing regions 318, 320 by a stem 326 which extends through the bottom of the chamber body 302 where it is connected to a drive system 303.

Each of the processing regions 318, 320 may include a gas distribution assembly 308 disposed through a chamber lid 304 to deliver gases into the processing regions 318, 320. The gas distribution assembly 308 of each processing region normally includes a gas inlet passage 340 which delivers gas from a gas flow controller 319 into a gas distribution manifold 342, which is also known as a showerhead assembly. Gas flow controller 319 is used to control and regulate the flow rates of different process gases into the chamber. Other flow control components may include a liquid flow injection valve and liquid flow controller (not shown) if liquid precursors are used. The gas distribution manifold 342 comprises an annular base plate 348, a face plate 346, and a blocker plate 344 between the base plate 348 and the face plate 346. The gas distribution manifold 342 includes a plurality of nozzles (not shown) through which gaseous mixtures are injected during processing. An RF (radio frequency) source 325 provides a bias potential to the gas distribution manifold 342 to facilitate generation of a plasma between the showerhead assembly 342 and the pedestal 328. During a plasma-enhanced chemical vapor deposition process, the pedestal 328 may serve as a cathode for generating the RF bias within the chamber body 302. The cathode is electrically coupled to an electrode power supply to generate a capacitive electric field in the deposition chamber 300. Typically an RF voltage is applied to the cathode while the chamber body 302 is electrically grounded. Power applied to the pedestal 328 creates a substrate bias in the form of a negative voltage on the upper surface of the substrate. This negative voltage is used to attract ions from the plasma formed in the chamber 300 to the upper surface of the substrate.

In one embodiment, the electron beam generating system 150, similar to the electron beam generating system depicted in FIGS. 1-2, may be coupled to the chamber 300 to generate electron beam in each of the processing regions 318, 320. The plates, such as face plate 346 and blocker plate 344, included in the gas distribution assembly 308 may utilize as anode and cathode, as described above, for the electron beam generating system 150. It is noted that the electron beam generating system 150 may be an optional feature, removable from the chamber 300.

During processing, process gases are uniformly distributed radially across the substrate surface. The plasma is formed from one or more process gases or a gas mixture by applying RF energy from the RF power supply 325 to the gas distribution manifold 342, which acts as a powered electrode. Film deposition takes place when the substrate is exposed to the plasma and the reactive gases provided therein. The chamber walls 312 are typically grounded. The RF power supply 325 can supply either a single or mixed-frequency RF signal to the gas distribution manifold 342 to enhance the decomposition of any gases introduced into the processing regions 318, 320.

A system controller 334 controls the functions of various components such as the RF power supply 325, the drive system 303, the lift mechanism 306, the gas flow controller 319, and other associated chamber and/or processing functions. The system controller 334 executes system control software stored in a memory 338, which in the preferred embodiment is a hard disk drive, and can include analog and digital input/output boards, interface boards, and stepper motor controller boards. Optical and/or magnetic sensors are generally used to move and determine the position of movable mechanical assemblies.

The above CVD system description is mainly for illustrative purposes, and other plasma processing chambers may also be employed for practicing embodiments of the invention.

FIG. 4 illustrates a process flow diagram of a method 400 for forming an electron beam treated amorphous carbon layer according to one embodiment of the present invention. FIGS. 5A-5D is schematic cross-sectional view illustrating a film stack during various portions of a sequence for forming an electron beam treated amorphous carbon layer for use as a hardmask layer according to the method 400.

The method 400 begins at block 402 by providing a substrate 500 having a material layer 502 disposed thereon, as shown in FIG. 5A. The substrate 500 may have a substantially planar surface, an uneven surface, or a substantially planar surface having a structure formed thereon. In one embodiment, the material layer 502 may be a part of a film stack utilized to form a gate structure, a contact structure, an interconnection structure or shadow trench isolation (STI) structure in the front end or back end processes. In embodiments wherein the material layer 502 is not present, the process 400 be directly formed in the substrate 500.

In one embodiment, the material layer 502 maybe a silicon layer utilized to form a gate electrode. In another embodiment, the material layer 502 may include a silicon oxide layer, or a silicon oxide layer deposited over a silicon layer. In yet another embodiment, the material layer 502 may include one or more layers of other dielectric materials utilized to fabricate semiconductor devices. Suitable examples of the dielectric layers include silicon oxide, silicon nitride, silicon oxyntride, silicon carbide, or any suitable low-k or porous dielectric material. In still another embodiment, the material layer 502 does not include any metal layers.

At block 404, an amorphous carbon layer 504 is formed on the material layer 502, as shown in FIG. 5B. The amorphous carbon layer 504 may be formed in a chemical vapor deposition (CVD) chamber, such as the CVD chamber depicted in FIG. 3. Alternatively, the amorphous carbon layer 504 may be depsited in any suitable deposition chamber, such a chemical vapor deposition (CVD), atomic layer deposition (ALD), cyclical layer deposition (CLD), physical vapor deposition (PVD), or the like as needed. In an exemplary embodiment depicted herein, the amorphous carbon layer 504 is depicted in the CVD chamber 300 depicted in FIG. 3.

During deposition of the amorphous carbon layer 504, a gas mixture may be supplied into the processing chamber 300 for processing. The gas mixture includes at least a hydrocarbon compound and an inert gas. In one embodiment, hydrocarbon compound has a formula CₓH_{y}, where x has a range between 1 and 12 and y has a range of between 4 and 26. More specifically, aliphatic hydrocarbons include, for example, alkanes such as methane, ethane, propane, butane, pentane, hexane, heptane, octane, nonane, decane and the like; alkenes such as propene, ethylene, propylene, butylene, pentene, and the like; dienes such as hexadiene butadiene, isoprene, pentadiene and the like; alkynes such as acetylene, vinylacetylene and the like. Alicyclic hydrocarbons include, for example, cyclopropane, cyclobutane, cyclopentane, cyclopentadiene, toluene and the like. Aromatic hydrocarbons include, for example, benzene, styrene, toluene, xylene, pyridine, ethylbenzene, acetophenone, methyl benzoate, phenyl acetate, phenol, cresol, furan, and the like. Additionally, alpha-terpinene, cymene, 1,1,3,3,-tetramethylbutylbenzene, t-butylether, t-butylethylene, methyl-methacrylate, and t-butylfurfurylether may be utilized. Additionally, alpha-terpinene, cymene, 1,1,3,3,-tetramethylbutylbenzene, t-butylether, t-butylethylene, methyl-methacrylate, and t-butylfurfurylether may be selected. In an exemplary embodiment, the hydrocarbon compounds are propene, acetylene, ethylene, propylene, butylenes, toluene, alpha-terpinene. In a particular embodiment, the hydrocarbon compound is propene (C₃H₆) or acetylene.

Alternatively, one or more hydrocarbon compounds may be mixed with the hydrocarbon compound in the gas mixture supplied to the process chamber. A mixture of two or more hydrocarbon compounds may be used to deposit the amorphous carbon material.

The inert gas, such as argon (Ar) or helium (He), is supplied with the gas mixture into the process chamber 100. Other carrier gases, such as nitrogen (N₂) and nitric oxide (NO), hydrogen (H₂), ammonia (NH₃), a mixture of hydrogen (H₂) and nitrogen (N₂), or combinations thereof, may also be used to control the density and deposition rate of the amorphous carbon layer. The addition of H₂ and/or NH₃ may also be used to control the hydrogen ratio (e.g., carbon to hydrogen ratio) of the deposited amorphous carbon layer. The hydrogen ratio present in the amorphous carbon film provides control over layer properties, such as reflectivity.

In one embodiment, an inert gas, such as argon (Ar) or helium (He) gas, is supplied with the hydrocarbon compound, such as propene (C₃H₆) or acetylene, into the process chamber to deposit the amorphous carbon film. The inert gas provided in the gas mixture may assist control of the optical and mechanical properties of the as-deposited layer, such as the index of refraction (n) and the absorption coefficient (k), hardness, density and elastic modulus of the amorphous carbon layer 504.

In one embodiment, the absorption coefficient (k) of the deposited amorphous carbon film may be controlled at between about 0.2 and about 1.8 at a wavelength about 633 nm, and between about 0.4 and about 1.3 at a wavelength about 243 nm, and between about 0.3 and about 0.6 at a wavelength about 193 nm.

In one embodiment, the absorption coefficient of the amorphous carbon film 504 may also be varied as a function of the deposition temperature. In particular, as the temperature increases, the absorption coefficient (k) of the deposited layer likewise increases. Accordingly, a well selected combination of process temperature and the ratio of inert gas to hydrocarbon compound supplied in the gas mixture may be utilized to adjust the deposited carbon film with the desired stress level and index of refraction (n) and the absorption coefficient (k).

During deposition, the substrate temperature may be controlled between about 300 degrees Celsius and about 800 degrees Celsius. The hydrocarbon compound, such as propene (C₃H₆), may be supplied in the gas mixture at a rate between about 200 sccm and about 3000 sccm, such as between about 400 sccm and about 2000 sccm. The inert gas, such as Ar gas, may be supplied in the gas mixture at a rate between about 200 sccm and about 10000 sccm, such as about 1200 sccm and about 8000 sccm. A RF source power of between about 400 Watts to about 2000 Watts, such as 800 Watts to about 1600 Watts, or a power density between 1.35 Watt/cm₂ and about 2.35 Watt/cm₂, may be applied to maintain a plasma formed from the gas mixture. The process pressure may be maintained at about 1 Torr to about 20 Torr, such as about 2 Torr and about 12 Torr, for example, about 4 Torr to about 9 Torr. The spacing between the substrate and showerhead may be controlled at about 200 mils to about 1000 mils.

At block 406, after the amorphous carbon layer 504 is formed on the substrate 500, an electron beam (e-beam) treatment process is performed on the amorphous carbon layer 504 to form a treated carbon layer 506 on the material layer 502, as shown in FIG. 5C. In one embodiment, the treatment process may be performed in an electron beam treatment chamber, such as the electron beam apparatus 100 depicted in FIGS. 1-2. In this particular embodiment, the amorphous carbon deposition process at block 404 and the electron beam treatment process at block 406 are performed ex-situ respectively at a CVD chamber and an electron beam apparatus, such as the CVD chamber 300 and the electron beam apparatus 100 depicted in FIGS. 1-3. The CVD chamber and the electron beam apparatus may be incorporated in a cluster system so that the substrate being processed in between these two chambers does not expose to atmosphere or ambient environment and can be proceed under vacuum (e.g., without breaking vacuum).

In another embodiment, the treatment process may be performed in a CVD chamber equipped with an electron beam generating system, such as the electron beam generating system 150 disposed in the CVD chamber 300 depicted in FIG. 3. In this particular embodiment, the electron beam treatment process may be performed in-situ with the amorphous carbon layer deposition process at block 404 without removing the substrate from the CVD chamber 300.

During the electron beam treatment process, an electron beam radiation is directed to the substrate 500 until a sufficient dose has accumulated to treat the amorphous carbon layer 504 and affect certain film properties, such as refractive index, solidity, moisture content, hardness, resistance to etchant chemical, e.g., wet or dry etching rate, and dielectric constant. A total energy dose of between about 10 micro-Coulombs per square centimeter (μC/cm²) and about 10,000 micro-Coulombs per square centimeter (μC/cm²) is treated to the amorphous carbon layer 504. The electron beam is delivered at a high energy of between about 1000 volts and about 15000 volts to cathode 122. A bias energy to the anode 126 of between about 10 volts and about 100 volts is also delivered. The electron beam current ranges between about 1 mA and about 10 mA. The process pressure may be controlled between about 25 mTorr and about 75 mTorr. The substrate temperature is maintained at between about 30 degrees Celsius and about 200 degrees Celsius.

The treatment gas that may be used includes Ar, He, N₂, O₂, N₂O, H₂, NO₂ and the like. In an exemplary embodiment herein, the treatment gas as used is Ar gas. In one embodiment, the Ar gas supplied during the treatment process is controlled at between about 25 sccm and about 250 sccm.

In one embodiment, the high energy and/or the bias energy as generated during the electron beam treatment process may be gradually tuned down or tuned up as needed to control treatment efficiency. In an exemplary embodiment, the high energy as applied during the electron beam treatment process may be tuned down while the bias energy may be tuned up. In at least one embodiment, the electron beam treatment process is a three step process in which the high energy applied in each step (from the first step to the third step) is gradually tuned down while the bias energy applied in each step (from the first step to the third step) is gradually tuned up. In one example, in the first step of the electron beam treatment process, the high energy to the cathode 122 is controlled at between about 1000 volts and about 20000 volts, such as about 15000 volts while the bias energy to the anode 126 is controlled at between about 10 volts and about 100 volts, such as about 20 volts. The first step may be performed at a first time period between about 1 minutes and about 15 minutes. In the second step of the electron beam treatment process, the high energy is controlled at between about 1000 volts and about 15000 volts, such as about 6000 volts while the bias energy is controlled at between about 10 volts and about 100 volts, such as about 35 volts. The second step may be performed at a first time period between about 1 minutes and about 15 minutes. In the third step of the electron beam treatment process, the high energy is controlled at between about 1000 volts and about 15000 volts, such as about 3000 volts while the bias energy is controlled at between about 10 volts and about 100 volts, such as about 45 volts. The third step may be performed at a first time period between about 1 minutes and about 15 minutes.

After the electron-beam treatment process, it is believed that the treated amorphous carbon layer 506 may have an improved etching resistance as compared to conventional amorphous carbon film. The treatment process may densify the bonding structure of the amorphous carbon layer 506, thereby increasing the bonding energy of the carbon bonds. As the bonding energy of the carbon bonds in the treated amorphous carbon layer 506 is increased, the treated amorphous carbon layer 506 becomes more resistant to aggressive etchants used during the etching process. In one embodiment, the etching rate of the treated amorphous carbon layer 506 may have about 10 percent to 125 percent lower etch rate than untreated, e.g., conventional, amorphous carbon layer. In one embodiment, the treated amorphous carbon layer 506 may have an etching rate of between about 6 nm per minute and about 30 nm per minute when exposed to etchants.

Additionally, a thickness loss of about 70 Å to 80 Å may be found on the treated amorphous carbon layer 506 after the electron beam treatment process at block 406. The refractive index and absorption coefficient (k) remain substantially similar to the untreated amorphous carbon layer 504. In one embodiment, the absorption coefficient (k) of the deposited amorphous carbon film may be controlled at between about 0.2 and about 1.8 at a wavelength about 633 nm, and between about 0.4 and about 1.3 at a wavelength about 243 nm, and between about 0.3 and about 0.6 at a wavelength about 193 nm.

At block 408, after the electron beam treatment process, an etching process may be performed to etch the material layer 502 using the treated amorphous carbon layer 506 as a hardmask layer. The etching process is performed to form openings 508 in the material layer 502, using the treated amorphous carbon layer 506 as an etching hardmask layer, as shown in FIG. 5D. As discussed above, as the treated amorphous carbon layer 506 may have a higher etching resistance, as compared to conventional untreated amorphous carbon layer, using the treated amorphous carbon layer 506 as the hardmask during an etching process may assist sustaining the feature transfer to the material layer 502 until completion of the etching process to form desired profile and dimension.

In one embodiment, the material layer 502, as well as the treated amorphous carbon layer 506, is etched by an etching gas mixture supplied in an etching chamber. In one embodiment, the etching gas mixture may include at least a fluorine containing gas. In one embodiment, the etching gas mixture may include C₄F₈ (or C₄F₆) and, CH₂F₂, provided at a rate of between about 20 sccm and about 200 sccm (i.e., a C₄F₈:CH₂F₂, flow ratio ranging from 10:1 to 1:20, such as about 1:2), oxygen (O₂) at a rate of about 10 sccm to about 40 sccm (i.e., a C₄F₈:O₂, flow ratio ranging from 1:10 to 20:1, such as about 1:2.7), and argon (Ar) at a rate of about 20 sccm to about 1000 sccm. Power is provided to an inductively coupled antenna in the range of between about 500 W to about 1500 W. A first cathode bias power of between about 100 W and about 850 W and a second cathode bias power of between about 200 W and about 8000 W is delivered to the CVD chamber 300. The substrate is maintained at a temperature of between about 50 and about 200 degrees Celsius at a pressure in the process chamber between about 2 mTorr and 40 mTorr.

One process recipe provides C₄F₈ at a rate of 30 sccm, CH₂F₂ at a rate of 60 sccm (i.e., a C₄F₈:CH₂F₂ flow ratio of about 1:2), O₂ at a rate of 82 sccm, (i.e., a C₄F₈:O₂ flow ratio of about 1:2.7), applies 150 W of source power to the antenna, 750 W of a first bias power, 6000 W of a second bias power, maintains a wafer temperature of 30 degrees Celsius, and maintains a pressure of 25 mTorr.

The method 400 is particularly useful for the process used the treated amorphous carbon layer 506 as a hardmask layer when performing front end process (FEOL) prior to metallization process in a semiconductor device manufacture process. Suitable frond end process (FEOL) includes gate manufacture applications, contact structure applications, shallow trench isolation (STI) process, and the like.

In the embodiments wherein the treated amorphous carbon film 506 is used as an etch stop layer or used as different films for different process purposes, the mechanical or optical properties of the film may be adjusted as well to meet the particular process purposes. For example, in the embodiment wherein the treated amorphous carbon film 506 is used as an etch stop layer, the mechanical properties of the film for providing a high selectivity to prevent over-etching the underlying layers may weight more than its optical properties, or vise versa.

Thus, a method for treating an amorphous carbon layer having both desired mechanical and optical film properties are provided. The method advantageously improves the mechanical properties, such as stress, hardness, etching resistance, and density of the treated amorphous carbon film. The improved mechanical properties of the carbon film provides high film selectivity and etching resistance for the subsequent etching process while maintaining desired range of the film optical properties, such as index of refraction (n) and the absorption coefficient (k), for the subsequent lithography process.

While the foregoing is directed to embodiments of the present invention, other and further embodiments of the invention may be devised without departing from the basic scope thereof, and the scope thereof is determined by the claims that follow.

What is claimed is:

1. A method of treating an amorphous carbon film, comprising:
providing a substrate having a material layer disposed;
forming an amorphous carbon layer on the material layer; and
performing an electron beam treatment process on the amorphous carbon layer.

2. The method of claim 1, further comprising:
etching the material layer using the treated amorphous carbon layer as a hardmask layer.

3. The method of claim 1, wherein performing the electron beam treatment processing further comprises:
providing a first high voltage level and a first bias voltage level to generate an electron beam to the amorphous carbon layer for a first period of time.

4. The method of claim 3, further comprising:
providing a second high voltage level and a second bias voltage level to generate the electron beam that strikes the amorphous carbon layer for a second period of time, wherein the second high voltage level is less than the first high voltage level, and the second bias voltage level is greater than the first bias voltage.

5. The method of claim 4, further comprising:
providing a third high voltage level and a third bias voltage level to generate the electron beam to the amorphous carbon layer for a third period of time, wherein the third high voltage level is less than the second high voltage level and the third bias voltage level is greater than the second bias voltage.

6. The method of claim 1, performing the electron beam treatment processing further comprises:
supplying an argon gas to the amorphous carbon layer during the electron beam treatment process.

7. The method of claim 1, wherein the treated amorphous carbon layer has about 70 Å and 80 Å thickness during the treatment process.

8. The method of claim 7, wherein the etching rate of the treated amorphous carbon layer is between about 6 nm per minute and about 30 nm per minute when exposed to etchants.

9. The method of claim 1, wherein the treated amorphous carbon layer has about 10 percent to 125 percent of lower etching rate than the untreated amorphous carbon layer.

10. The method of claim 1, wherein the material layer is selected from a group consisting of silicon oxide, silicon nitride, silicon oxyntride, silicon carbide, low-k and porous dielectric material.

11. The method of claim 1, wherein performing the electron beam treatment processing further comprises:
treating an energy dose of between about 10 micro-Coulombs per square centimeter (μC/cm²) and about 10000 micro-Coulombs per square centimeter (μC/cm²) to the amorphous carbon layer.

12. The method of claim 1, wherein performing the electron beam treatment processing further comprises:
applying an electron beam current ranging between about 1 mA and about 10 mA to the amorphous carbon layer.

13. A method to perform an electron beam treatment process on an amorphous carbon layer comprising:
providing a substrate having an amorphous carbon layer disposed thereon;
performing an electron beam treatment process on the amorphous carbon layer, wherein the electron beam treatment process further comprises:
providing a first high voltage level and a first bias voltage level to generate an electron beam to the amorphous carbon layer for a first period of time;
providing a second high voltage level and a second bias voltage level to generate the electron beam to the amorphous carbon layer for a second period of time, wherein the second high voltage level is less than the first high voltage level and the second bias voltage level is greater than the first bias voltage; and
providing a third high voltage level and a third bias voltage level to generate the electron beam to the amorphous carbon layer for a third period of time, wherein the third high voltage level is less than the second high voltage level and the third bias voltage level is greater than the second bias voltage.

14. The method of claim 13, wherein the first high voltage level is controlled at between about 1000 volts and about 20000 volts and the first bias voltage level is controlled at between about 10 volts and about 1000 volts.

15. The method of claim 13, wherein the second high voltage level is controlled at between about 1000 volts and about 15000 volts and the second bias voltage level is controlled at between about 10 volts and about 100 volts.

16. The method of claim 13, wherein the third high voltage level is controlled at between about 1000 volts and about 15000 volts and the third bias voltage level is controlled at between about 10 volts and about 100 volts.

17. The method of claim 13, wherein the treated amorphous carbon layer has about 10 percent to 125 percent of lower etching rate than the amorphous carbon layer prior to the treatment process.

18. The method of claim 13, wherein performing the electron beam treatment processing further comprises:
treating a total energy dose of between about 10 micro-Coulombs per square centimeter (μC/cm²) and about 10000 micro-Coulombs per square centimeter (μC/cm²) to the amorphous carbon layer.

19. A method of treating an amorphous carbon film using as an hardmask layer during an etching process, comprising:
forming an amorphous carbon layer on a material layer disposed on a substrate; and
performing an electron beam treatment process on the amorphous carbon layer; and
etching the material layer using the treated amorphous carbon layer as a hardmask layer, wherein the electron beam treatment process further comprises:
providing a first high voltage level and a first bias voltage level to generate an electron beam to the amorphous carbon layer for a first period of time;
providing a second high voltage level and a second bias voltage level to generate the electron beam to the amorphous carbon layer for a second period of time, wherein the second high voltage level is less than the first high voltage level and the second bias voltage level is greater than the first bias voltage; and
providing a third high voltage level and a third bias voltage level to generate the electron beam to the amorphous carbon layer for a third period of time, wherein the third high voltage level is less than the second high voltage level and the third bias voltage level is greater than the second bias voltage.

20. The method of claim 19, wherein performing the electron beam treatment processing further comprises:
treating the amorphous carbon layer with a total energy dose of between about 10 micro-Coulombs per square centimeter (μC/cm²) and about 10000 micro-Coulombs per square centimeter (μC/cm²) to the amorphous carbon layer.
